(19) United States
(12) Patent Application Publication
(10) Pub. No.: US 2018/0175613 A1
(43) Pub. Date: Jun. 21, 2018

(54) TRANSMISSION CABLE STRUCTURE WITH CAPACITOR DEVICE

(71) Applicant: WEN-HUA LIN, TAOYUAN CITY (TW)

(72) Inventor: WEN-HUA LIN, TAOYUAN CITY (TW)

(21) Appl. No.: 15/447,401

(22) Filed: Mar. 2, 2017

(30) Foreign Application Priority Data
Dec. 16, 2016 (TW) 105219243

(51) Int. Cl. H02H 9/00; H01G 11/74; H01G 11/30; H03H 7/06; H01R 24/28; H01R 24/64

(52) U.S. Cl. CPC H02H 9/005; H01G 11/74; H01G 11/30; H01R 2107/00; H01R 24/28; H01R 24/64; H03H 7/06

(57) ABSTRACT

A transmission cable structure with capacitor device includes two connectors and positive and negative electrode conductive wires connected to the connectors and a capacitor device securely disposed between the connectors. The capacitor device has a first electrode connected to the positive electrode conductive wire and a second electrode connected to the negative electrode conductive wire. When the connectors are respectively connected with a first and a second electrical apparatuses, the capacitor device and the second electrical apparatus form a parallel circuit. When the first electrical apparatus supplies power for the second electrical apparatus, the capacitor device is charged by the first electrical apparatus to charge the second electrical apparatus, whereby the instantaneous surges are absorbed to protect the second electrical apparatus from the instantaneous surges. Also, a filtering function is provided. The capacitor device also can enhance the data transmission speed.

### BACKGROUND OF THE INVENTION

### 1. Field of the Invention

The present invention relates generally to a transmission cable structure with capacitor device, and more particularly to a transmission cable structure, which can absorb surges, filter the wave and enhance data transmission speed.

### 2. Description of the Related Art

The existent electrical apparatuses are all charged or supply power or transmit data via transmission cables, such as tablets, intelligent mobile phones, mobile power banks, digital cameras, keyboards, mice or mobile hard disks. The conventional transmission cable structure includes two connectors respectively connected with at least two ends of multiple positive and negative electrode conductive wires or grounding wire, such as D-type, G57, DIN, HDMI or USB connectors. According to the requirement of circuit design, the respective conductive wires are respectively soldered on multiple conductive terminals of the connectors. In this case, the connectors at two ends of the transmission cable can be respectively connected to the connectors of two electrical apparatuses, whereby the two electrical apparatuses are electrically connected via the two connectors. In addition, the transmission cable can be quickly installed/uninstalled to facilitate the use.

When the conventional electrical apparatuses transmit electrical power or data, the surges will be inevitably generated. This is mainly because the thunder and lightning will generate thunder surges or the opening/closing of the circuit will cause opening/closing surges. The opening/closing surges are the surges generated in the instant of closing the circuit. In general, the surges are caused by the electronic components such as the relay, switch, solenoid winding, fuse, transistor or the thyristor in IC. The surges generated when supplying power is apt to cause mis-operation of the circuit of the electrical apparatus or even cause damage of the electrical apparatus due to override of the circuit. Moreover, after a long period of interference by the surges, the circuit of the electrical apparatus is easy to cause shortening of the lifetime of the electronic components.

In order to avoid the interference of the surges to the electrical apparatus, many electrical apparatuses are additionally equipped with circuit protection module. For example, a circuit protection module can be inbuilt in the charging circuit of an intelligent mobile phone. The power can be transmitted to the battery of the intelligent mobile phone via the transmission cable and circuit protection module to charge the battery. In charging, the circuit protection module can eliminate the surges generated by the power supply to protect the charging circuit as well as the battery. However, not all the electrical apparatuses have the design of the circuit protection module. Many electrical apparatuses and most of the internal circuits connected to the multiple connectors of the electrical apparatuses lack circuit protection module. With respect to the above problem, the conventional transmission cable still has no structural design for eliminating the surges and protecting the electrical apparatus.

Even if some of the electrical apparatuses have circuit protection module to protect the circuits and electronic components of the electrical apparatuses from being damaged by the thunder surges, the circuit protection module itself often is easy to damage after encountering one time of thunder surge. In this case, the circuit protection module will lose its surge elimination ability. Furthermore, the service cost for the circuit protection module of the circuit of the electrical apparatus is generally higher.

In addition, various communication or AV electrical apparatuses capable of dealing with 3G, 4G or over 4G data are currently very popularly used and the amount of the accessed data has become larger and larger. However, the data access and transmission speed of the existent transmission cable is still quite low so that the data access time can be hardly saved.

It is therefore tried by the applicant to provide a transmission cable structure with capacitor device to solve the above problems of the conventional transmission cable.

### SUMMARY OF THE INVENTION

It is therefore a primary object of the present invention to provide a transmission cable structure with capacitor device, which can absorb surges and filter the wave.

To achieve the above and other objects, the transmission cable structure with capacitor device of the present invention includes:

a first connector and a second connector, each of the first and second connectors having an electrical mating section, at least one anode terminal and at least one cathode terminal, the anode terminal and the cathode terminal serving to transmit electrical power respectively via the electrical mating sections;
at least one positive electrode conductive wire, two ends of the positive electrode conductive wire being respectively connected to the anode terminal of the first connector and the anode terminal of the second connector;
at least one negative electrode conductive wire, two ends of the negative electrode conductive wire being respectively connected to the cathode terminal of the first connector and the cathode terminal of the second connector; and
a capacitor device disposed between the first and second connectors, the capacitor device having a first electrode and a second electrode, the first electrode of the capacitor device being connected to the positive electrode conductive wire, while the second electrode of the capacitor device being connected to the negative electrode conductive wire. The first electrode of the capacitor device is a positive electrode, while the second electrode of the capacitor device is a negative electrode.

According to the above structure, when the first and second connectors are respectively electrically connected with a first electrical apparatus and a second electrical apparatus, the capacitor device and the second electrical apparatus forma parallel circuit. When the first electrical apparatus supplies power for the second electrical apparatus, the capacitor device is charged by the first electrical apparatus to charge the second electrical apparatus. By means of the charging/discharging effect of the capacitor device, the instantaneous surges possibly generated when charged by the first electrical apparatus are absorbed to prevent the second electrical apparatus from being affected by the instantaneous surges. Also, a filtering function is provided to supply more stable power for the second electrical apparatus.

The present invention further provides a transmission cable structure with capacitor device, which can absorb surges, filter the wave and enhance data transmission speed. The capacitor device can be a supercapacitor (or so-called electrical double-layer capacitor). The supercapacitor has electrodes made of ruthenium or tantalum material. The supercapacitor has the advantages of low equivalent series resistance, short charging/discharging time, extremely high capacitance, high power density, etc. Accordingly, when the first electrical apparatus supplies power for the second electrical apparatus or transmits data to the second electrical apparatus, the supercapacitor not only can further enhance the circuit protection effect such as surge absorption effect and filtering effect, but also can more effectively increase the data transmission speed.

Accordingly, by means of the circuit design of the capacitor device connected to the transmission cable in parallel, the present invention is able to provide surge absorption and filtering effects for an existent electrical apparatus without circuit protection module. Also, the present invention increases the data transmission speed and is able to provide a low-cost circuit protection structure for an electrical apparatus already having circuit protection module.

In the above transmission cable structure with capacitor device, at least one first resistor is serially connected between one of the first and second electrodes of the capacitor device and the positive electrode conductive wire.

In the above transmission cable structure with capacitor device, the capacitor device is connected to a circuit protection module and the circuit protection module is serially connected to at least one second resistor.

In the above transmission cable structure with capacitor device, a receiving box is securely disposed on the positive and negative electrode conductive wires and the capacitor device is disposed in the receiving box.

The present invention can be best understood through the following description and accompanying drawings, wherein:

### BRIEF DESCRIPTION OF THE DRAWINGS

FIG. 1 is a perspective view of the present invention in use state;

FIG. 2 is a circuit diagram of the present invention in use state according to FIG. 1; and

FIG. 3 is a circuit diagram of a modified embodiment of the present invention according to FIG. 2.

### DETAILED DESCRIPTION OF THE PREFERRED EMBODIMENTS

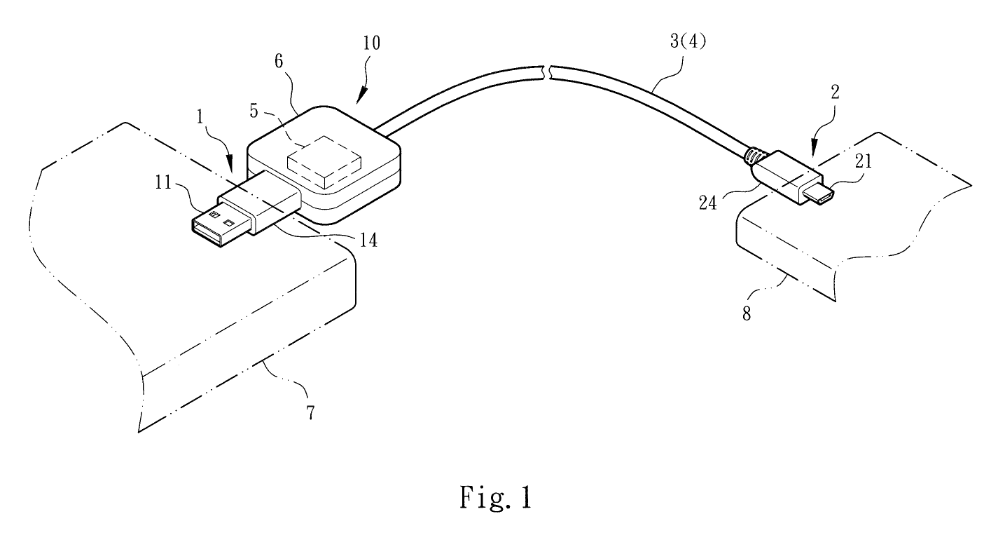

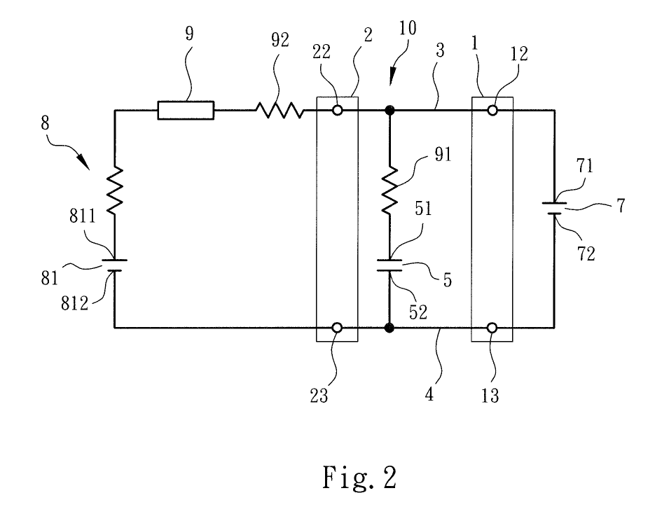

Please refer to FIGS. 1 and 2. The transmission cable structure with capacitor device of the present invention includes a first connector 1, a second connector 2, at least one positive electrode conductive wire 3, at least one negative electrode conductive wire 4 and a capacitor device 10. Each of the first and second connectors 1, 2 has an electrical mating section 11, 21, at least one anode terminal 12, 22 and at least one cathode terminal 13, 23. The anode terminal 12 and the cathode terminal 13 of the first connector 1 respectively extend to the electrical mating section 11, whereby the anode terminal 12 and the cathode terminal 13 of the first connector 1 can transmit electrical power or data via the electrical mating section 11. The anode terminal 22 and the cathode terminal 23 of the second connector 2 respectively extend to the electrical mating section 21, whereby the anode terminal 22 and the cathode terminal 23 of the second connector 2 can transmit electrical power or data via the electrical mating section 21.

As shown in the drawings, two ends of the positive electrode conductive wire 3 are respectively connected to the anode terminal 12 of the first connector 1 and the anode terminal 22 of the second connector 2 and two ends of the negative electrode conductive wire 4 are respectively connected to the cathode terminal 13 of the first connector 1 and the cathode terminal 23 of the second connector 2. The electrical mating section 11 of the first connector 1 and the positive and negative electrode conductive wires 3, 4 in adjacency to the electrical mating section 11 are enclosed in an insulation seat body 14. The electrical mating section 21 of the second connector 2 and the positive and negative elect rode conductive wires 3, 4 in adjacency to the electrical mating section 21 are enclosed in an insulation seat body 24.

As shown in FIG. 2, the capacitor device 10 can be a capacitor or a supercapacitor. In this embodiment, the capacitor device 10 is a supercapacitor (or so-called electrical double-layer capacitor). The capacitor device 10 is disposed between the first and second connectors 1, 2 and securely arranged on the positive and negative electrode conductive wires 3, 4. The supercapacitor 5 has a first electrode 51 and a second electrode 52. The first electrode 51 is a positive electrode, while the second electrode 52 is a negative electrode. The first electrode 51 of the supercapacitor 5 is connected to the positive electrode conductive wire 3, while the second electrode 52 of the supercapacitor 5 is connected to the negative electrode conductive wire 4.

The supercapacitor 5 employs high-surface-area and high-porosity ruthenium or tantalum material as the electrodes. By means of the charge separation phenomenon caused by coulomb electrostatic force between the interfaces of the electrodes and the electrolyte, the supercapacitor 5 can achieve the object of power storage. Therefore, the supercapacitor 5 has the advantages of low equivalent series resistance, fast charging speed, high charging/discharging efficiency, extremely high capacitance, super-high large current discharging capability, high energy conversion efficiency, small energy loss, large current energy circulation efficiency 90%, high power density, long circulation life time, etc.

As shown in FIG. 1, in a preferred embodiment, a receiving box 6 is securely disposed on the positive and negative electrode conductive wires 3, 4. The supercapacitor 5 is disposed in the receiving box 6, whereby the receiving box 6 can provide protection effect for the supercapacitor 5. As shown in FIG. 2, in another preferred embodiment, the first electrode 51 of the capacitor device 10 is connected to or serially connected to at least one first resistor 91. Alternatively, the second electrode 52 of the capacitor device 10 is connected to or serially connected to at least one first resistor 91. The first resistor 91 serves to provide voltage division and voltage reduction effect for the supercapacitor 5.

FIG. 2 further shows that in another preferred embodiment, the supercapacitor 5 can be alternatively connected to a circuit protection module 9. For example, the circuit protection module 9 is connected to or serially connected to the positive electrode conductive wire 3 via the anode terminal 22 of the second connector 2. Alternatively, the circuit protection module 9 is connected to or serially connected to the negative electrode conductive wire 4 via the cathode terminal 23 of the second connector 2. Still alternatively, the circuit protection module 9 is connected to or serially connected to the first electrode 51 or the second electrode 52 of the supercapacitor 5. Moreover, the circuit protection module 9 can be serially connected to a second resistor 92, whereby the second resistor 92 is connected between the circuit protection module 9 and the first electrode 51 of the supercapacitor 5.

As shown in FIGS. 1 and 2, when using a first electrical apparatus 7 (such as a mobile power bank) to charge a second electrical apparatus 8 (such as an intelligent mobile phone), the electrical mating sections 11, 21 of the first and second connectors 1, 2 of the transmission cable of the present invention are respectively connected with the connector of the first electrical apparatus 7 and the connector of the second electrical apparatus 8. In this case, the circuit protection module 9 is connected between the capacitor device 10 (or the supercapacitor 5) and the second electrical apparatus 8. The first electrode 51 of the supercapacitor 5 is connected to the power supply positive electrode terminal 71 of the first electrical apparatus 7 via the first resistor 91, the positive electrode conductive wire 3 and the anode terminal 12. In addition, the first electrode 51 of the supercapacitor 5 is connected to the positive electrode terminal 811 of the battery 81 of the second electrical apparatus 8 via the first resistor 91, the positive electrode conductive wire 3, the anode terminal 12, the second resistor 92 and the circuit protection module 9. Also, the second electrode 52 of the supercapacitor 5 is respectively connected to the power supply negative electrode terminal 72 of the first electrical apparatus 7 and the negative electrode terminal 812 of the battery 81 of the second electrical apparatus 8 via two ends of the negative electrode conductive wire 4. At this time, the supercapacitor 5, the battery 81 of the second electrical apparatus 8 and the circuit protection module 9 form a parallel circuit. Accordingly, the supercapacitor 5 is charged by the power supply of the first electrical apparatus 7 to charge the battery 81 of the second electrical apparatus 8. By means of the fast charging/discharging property of the supercapacitor 5, the instantaneous surges possibly generated when charged by the first electrical apparatus 7 can be absorbed to prevent the circuit and the battery 81 of the second electrical apparatus 8 or the circuit protection module 9 from being affected by the instantaneous surges. Also, a filtering function is provided to supply more stable power for the second electrical apparatus 8. Even if the transmission cable and the supercapacitor 5 of the present invention are damaged by the surges, the second electrical apparatus 8 can be still secured from the affection of the surges.

When using the first electrical apparatus 7 (such as a computer) to transmit data to the second electrical apparatus 8 (such as an intelligent mobile phone), the supercapacitor 5 and the data access circuit of the second electrical apparatus 8 also form a parallel circuit. In this case, the first electrical apparatus 7 can transmit data to the second electrical apparatus 8 via the positive and negative electrode conductive wires 3, 4 and the supercapacitor 5. Accordingly, by means of the properties of fast charging/discharging speed, high energy conversion efficiency, extremely high capacitance, etc. of the supercapacitor 5, the data transmission speed can be effectively enhanced.

In a real test of 3G data transmission, the conventional transmission cable without parallel capacitor has a data downloading speed of 19.84 Mbps and a data uploading speed of 3.5 Mbps within a 30 ms time range. The transmission cable with the supercapacitor 5 of the present invention has a data downloading speed of 44.38 Mbps and a data uploading speed of 3.62 Mbps within a 36 ms time range. Therefore, the data transmission speed of the present invention is about 75% increased.

In a real test of 4G data transmission, the conventional transmission cable without parallel capacitor has a data downloading speed of 29.23 Mbps and a data uploading speed of 1.15 Mbps within a 49 ms time range. The transmission cable with the supercapacitor 5 of the present invention has a data downloading speed of 32.46 Mbps and a data uploading speed of 6.48 Mbps within a alms time range. Therefore, the data transmission speed of the present invention is about 85% increased.

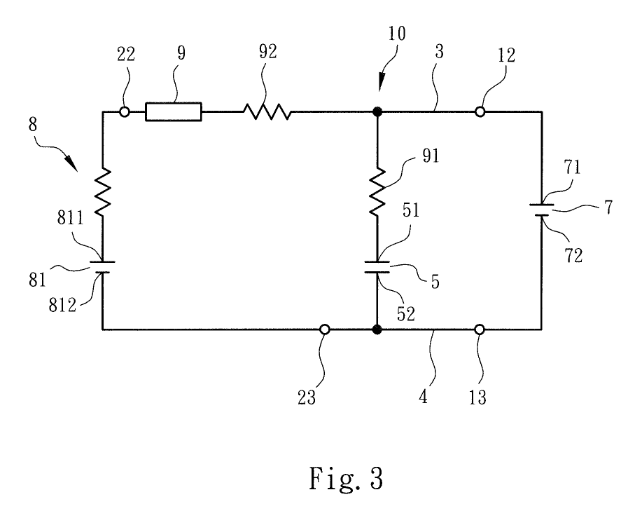

Please now refer to FIG. 3. In a modified embodiment, the above circuit protection module 9 and the second resistor 92 can be alternatively disposed on the positive electrode conductive wire 3 or the negative electrode conductive wire 4 of the transmission cable of the present invention. In this case, the circuit protection module 9 is serially connected to the positive electrode conductive wire 3 or the negative electrode conductive wire 4 or the circuit protection module 9 is serially connected to the first electrode 51 or the second electrode 52 of the supercapacitor 5, while the second resistor 92 is connected between the first electrode 51 of the supercapacitor 5 and the circuit protection module 9. Accordingly, the capacitor device 10 and the circuit protection module 9 provide multilevel protection effects for the circuit of the second electrical apparatus 8.

It should be noted that by means of the circuit design of the supercapacitor 5 (or the capacitor) connected to the transmission cable in parallel, the present invention is able to provide surge absorption and filtering effects for an existent electrical apparatus without circuit protection module. Also, the present invention apparently increases the data transmission speed and is able to provide a low-cost circuit protection structure for an electrical apparatus already having circuit protection module so as to prolong lifetime of the electrical apparatus and shorten the data access time.

The above embodiments are only used to illustrate the present invention, not intended to limit the scope thereof. Many modifications of the above embodiments can be made without departing from the spirit of the present invention.

What is claimed is:

1. A transmission cable structure with capacitor device, comprising:
a first connector and a second connector, each of the first and second connectors having an electrical mating section, at least one anode terminal and at least one cathode terminal, the anode terminal and the cathode terminal serving to transmit electrical power respectively via the electrical mating sections;
at least one positive electrode conductive wire, two ends of the positive electrode conductive wire being respectively connected to the anode terminal of the first connector and the anode terminal of the second connector;
at least one negative electrode conductive wire, two ends of the negative electrode conductive wire being respectively connected to the cathode terminal of the first connector and the cathode terminal of the second connector; and
a capacitor device disposed between the first and second connectors, the capacitor device having a first electrode and a second electrode, the first electrode of the capacitor device being connected to the positive electrode conductive wire, while the second electrode of the capacitor device being connected to the negative electrode conductive wire.

2. The transmission cable structure with capacitor device as claimed in claim 1, wherein the capacitor device is a capacitor or a supercapacitor.

3. The transmission cable structure with capacitor device as claimed in claim 2, wherein the supercapacitor has electrodes made of ruthenium or tantalum material.

4. The transmission cable structure with capacitor device as claimed in claim 1, wherein the first electrode of the capacitor device is a positive electrode, while the second electrode of the capacitor device is a negative electrode.

5. The transmission cable structure with capacitor device as claimed in claim 2, wherein the first electrode of the capacitor device is a positive electrode, while the second electrode of the capacitor device is a negative electrode.

6. The transmission cable structure with capacitor device as claimed in claim 3, wherein the first electrode of the capacitor device is a positive electrode, while the second electrode of the capacitor device is a negative electrode.

7. The transmission cable structure with capacitor device as claimed in claim 1, wherein at least one first resistor is serially connected between one of the first and second electrodes of the capacitor device and the positive electrode conductive wire.

8. The transmission cable structure with capacitor device as claimed in claim 2, wherein at least one first resistor is serially connected between one of the first and second electrodes of the capacitor device and the positive electrode conductive wire.

9. The transmission cable structure with capacitor device as claimed in claim 3, wherein at least one first resistor is serially connected between one of the first and second electrodes of the capacitor device and the positive electrode conductive wire.

10. The transmission cable structure with capacitor device as claimed in claim 4, wherein at least one first resistor is serially connected between one of the first and second electrodes of the capacitor device and the positive electrode conductive wire.

11. The transmission cable structure with capacitor device as claimed in claim 1, wherein the capacitor device is connected to a circuit protection module.

12. The transmission cable structure with capacitor device as claimed in claim 2, wherein the capacitor device is connected to a circuit protection module.

13. The transmission cable structure with capacitor device as claimed in claim 3, wherein the capacitor device is connected to a circuit protection module.

14. The transmission cable structure with capacitor device as claimed in claim 4, wherein the capacitor device is connected to a circuit protection module.

15. The transmission cable structure with capacitor device as claimed in claim 7, wherein the capacitor device is connected to a circuit protection module.

16. The transmission cable structure with capacitor device as claimed in claim 11, wherein the circuit protection module is serially connected to at least one second resistor.

17. The transmission cable structure with capacitor device as claimed in claim 12, wherein the circuit protection module is serially connected to at least one second resistor.

18. The transmission cable structure with capacitor device as claimed in claim 13, wherein the circuit protection module is serially connected to at least one second resistor.

19. The transmission cable structure with capacitor device as claimed in claim 14, wherein the circuit protection module is serially connected to at least one second resistor.

20. The transmission cable structure with capacitor device as claimed in claim 15, wherein the circuit protection module is serially connected to at least one second resistor.

21. The transmission cable structure with capacitor device as claimed in claim 1, wherein a receiving box is securely disposed on the positive and negative electrode conductive wires and the capacitor device is disposed in the receiving box.

22. The transmission cable structure with capacitor device as claimed in claim 2, wherein a receiving box is securely disposed on the positive and negative electrode conductive wires and the capacitor device is disposed in the receiving box.

23. The transmission cable structure with capacitor device as claimed in claim 3, wherein a receiving box is securely disposed on the positive and negative electrode conductive wires and the capacitor device is disposed in the receiving box.
